(19) United States
(12) Patent Application Publication
(10) Pub. No.: US 2017/0176671 A1
(43) Pub. Date: Jun. 22, 2017

(54) LIGHT PIPE STRUCTURE OF IMAGE SENSING DEVICE AND FABRICATING METHOD THEREOF

(71) Applicant: Powerchip Technology Corporation, Hsinchu (TW)

(72) Inventors: Tzu-Wen Kao, Chiayi County (TW); Yu-Yuan Lai, Miaoli County (TW); Chin-Yu Hsieh, Hsinchu City (TW)

(21) Appl. No.: 15/016,219

(22) Filed: Feb. 4, 2016

(30) Foreign Application Priority Data
Dec. 22, 2015 (TW) 104143073

(51) Int. Cl. G02B 6/02; H01L 27/146

(52) U.S. Cl. CPC G02B 6/02033; H01L 27/14625; H01L 27/14685

(57) ABSTRACT

A light pipe structure of an image sensing device including a substrate, a dielectric layer, and a light-pipe material layer is provided. The substrate has a light sensing region therein. The dielectric layer is disposed on the substrate. The dielectric layer has a light pipe therein, and the light pipe is located above the light sensing region. The light-pipe material layer is disposed in the light pipe and has a recessed curved surface.

### CROSS-REFERENCE TO RELATED APPLICATION

This application claims the priority benefit of Taiwan application serial no. 104143073, filed on Dec. 22, 2015. The entirety of the above-mentioned patent application is hereby incorporated by reference herein and made a part of this specification.

### BACKGROUND OF THE INVENTION

Field of the Invention

The invention relates to an image sensing device and a fabricating method thereof and more particularly relates to a light pipe structure of an image sensing device and a fabricating method thereof.

Description of Related Art

An image sensing device fabricated by a semiconductor fabricating process may be used for sensing light projected to a semiconductor substrate, such as complementary metal oxide semiconductor (CMOS). Such an image sensing device utilizes a sensing unit array to receive light energy and converts the same into digital data.

A method has been proposed to dispose a light pipe structure above the light sensing region for improving light sensitivity. However, how to capture and gather more incident light to further enhance the light sensitivity of the image sensing device remains an important issue in this field.

### SUMMARY OF THE INVENTION

The invention provides a light pipe structure of an image sensing device for capturing and gathering more incident light.

The invention provides a method for fabricating a light pipe structure of an image sensing device, and the light pipe structure fabricated by the method efficiently improves light sensitivity of the image sensing device.

The invention provides a light pipe structure of an image sensing device, which includes a substrate, a dielectric layer, and a light-pipe material layer. The substrate has a light sensing region therein. The dielectric layer is disposed on the substrate. The dielectric layer has a light pipe therein, and the light pipe is located above the light sensing region. The light-pipe material layer is disposed in the light pipe and has a recessed curved surface.

According to an embodiment of the invention, in the light pipe structure of the image sensing device, the recessed curved surface has a curvature radius of 636 nm-791 nm, for example.

According to an embodiment of the invention, in the light pipe structure of the image sensing device, the light-pipe material layer has a refractive index of 1.7-1.9, for example.

According to an embodiment of the invention, in the light pipe structure of the image sensing device, the refractive index of the light-pipe material layer is greater than a refractive index of a previous light transmission medium, for example.

According to an embodiment of the invention, the light pipe structure of the image sensing device further includes a protection layer. The protection layer is conformally disposed on the dielectric layer, and a portion of the protection layer is located between the light-pipe material layer and the dielectric layer.

The invention provides a method for fabricating a light pipe structure of an image sensing device, including the following steps. A substrate is provided. A light sensing region is formed in the substrate. A dielectric layer is formed on the substrate. A light pipe is formed in the dielectric layer by removing a portion of the dielectric layer above the light sensing region. A light-pipe material layer is formed in the light pipe, wherein the light-pipe material layer has a recessed curved surface.

According to an embodiment of the invention, in the fabricating method of the light pipe structure of the image sensing device, a Miming method of the light-pipe material layer includes the following steps. A light-pipe material is formed on the dielectric layer to fill the light pipe. The light-pipe material outside the light pipe is removed by performing a chemical mechanical polishing process on the light-pipe material using a fluff polishing pad.

According to an embodiment of the invention, in the fabricating method of the light pipe structure of the image sensing device, a slurry used in the chemical mechanical polishing process is CeO₂, SiO₂, or a combination thereof, for example.

According to an embodiment of the invention, in the fabricating method of the light pipe structure of the image sensing device, a polishing pressure of the chemical mechanical polishing process is 2.2 psi-3.2 psi, for example.

According to an embodiment of the invention, the fabricating method of the light pipe structure of the image sensing device further includes conformally forming a protection layer on the dielectric layer after forming the light pipe and before forming the light-pipe material layer.

Based on the above, in the light pipe structure of the image sensing device and the fabricating method provided by the invention, the light-pipe material layer is formed with the recessed curved surface that redirects the incident light for capturing and gathering more incident light to directly enter the light sensing region and thereby efficiently improving the light sensitivity of the image sensing device.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1A through FIG. 1C are schematic cross-sectional views showing a fabricating process of a light pipe structure of a sensing device according to an embodiment of the invention.

### DESCRIPTION OF THE EMBODIMENTS

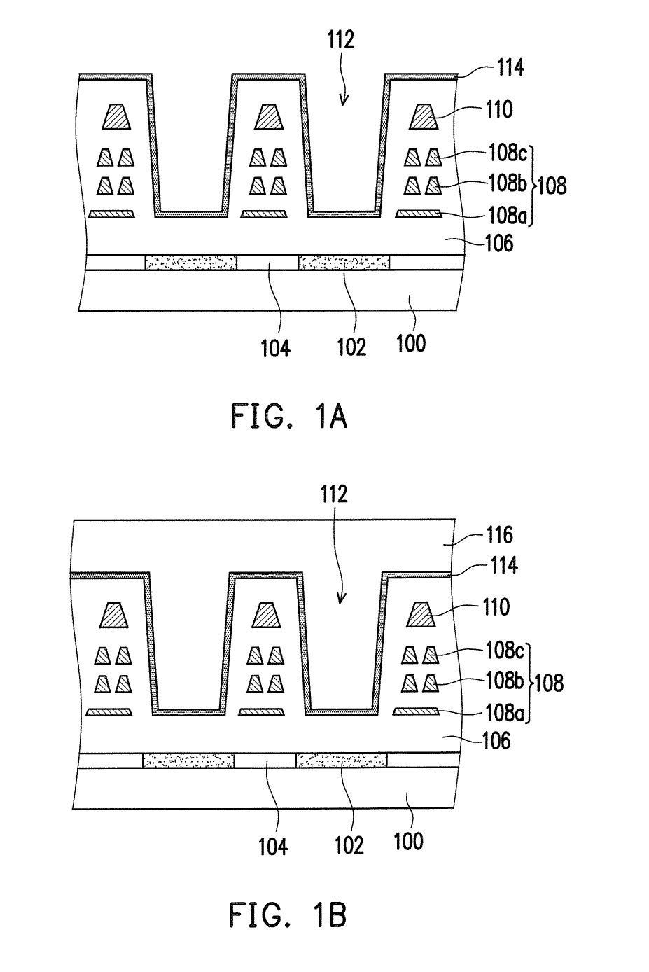

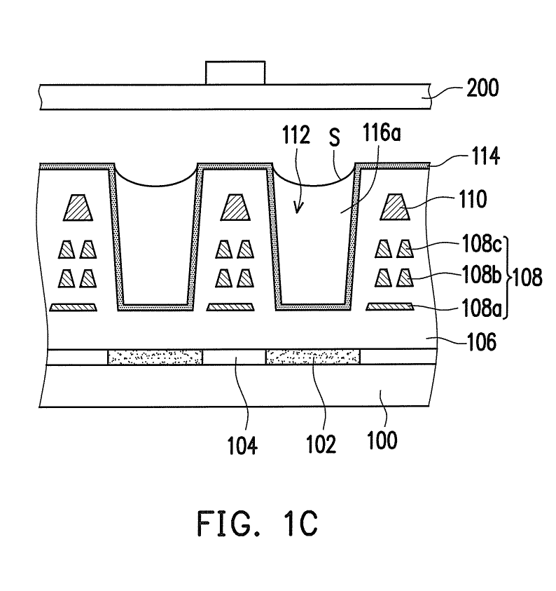

FIG. 1A through FIG. 1C are schematic cross-sectional views showing a fabricating process of a light pipe structure of a sensing device according to an embodiment of the invention. In this embodiment, an image sensing device is a complementary metal oxide semiconductor (CMOS) image sensor, for example.

With reference to FIG. 1A, a substrate 100 is provided. The substrate 100 is, for example, a silicon substrate. A light sensing region 102 is formed in the substrate 100. The light sensing region 102 is a photodiode, for example. Moreover, a plurality of isolation regions 104 may be formed in the substrate 100, and the light sensing region 102 is located between the isolation regions 104. The isolation region 104 is a shallow trench isolation structure, for example.

A dielectric layer 106 is formed on the substrate 100. The dielectric layer 106 has a refractive index of 1.4-1.5, for example. A material of the dielectric layer 106 is silicon dioxide, TEOS, or BPTEOS, for example. Although FIG. 1A illustrates a case where the dielectric layer 106 is a single layer, the dielectric layer 106 may in fact have a multi-layer structure. A method of forming the dielectric layer 106 is a chemical vapor deposition process, for example.

Furthermore, an interconnect structure 108 and a light-blocking metal layer 110 may be formed in the dielectric layer 106. The interconnect structure 108 may be used for electrical connection to a semiconductor device or an external power source. In this embodiment, the interconnect structure 108 includes a first metal layer 108a, a second metal layer 108b, and a third metal layer 108c, for example, but the invention is not limited thereto. Those skilled in the art may decide the number of metal layers in the interconnect structure 108 according to the requirements of the actual product design. A material of the interconnect structure 108 is copper, aluminum or tungsten, for example. A method of foaming the interconnect structure 108 is a damascene process or a combination of deposition, photolithography, and etching processes, for example.

The light-blocking metal layer 110 is disposed above the interconnect structure 108. The light-blocking metal layer 110 may prevent an incident light that is predetermined to enter a specific sensing unit from hitting another sensing unit, so as to suppress light interference. A material of the light-blocking metal layer 110 is copper, aluminum, or tungsten, for example. A method of forming the light-blocking metal layer 110 is a damascene process or a combination of deposition, photolithography, and etching processes, for example.

A light pipe 112 is formed in the dielectric layer 106 by removing a portion of the dielectric layer 106 above the light sensing region 102. A method of removing a portion of the dielectric layer 106 is a combination of photolithography and etching processes, for example.

In addition, a protection layer 114 may be formed conformally on the dielectric layer 106. The protection layer 114 may prevent moisture from entering the device, so as to improve reliability of the device. A material of the protection layer 114 is silicon nitride, for example. A method of forming the protection layer 114 is a chemical vapor deposition process, for example.

With reference to FIG. 1B, a light-pipe material 116 is formed on the dielectric layer 106 to fill the light pipe 112. The light-pipe material 116 is polysiloxane, for example. A method of forming the light-pipe material 116 is a spin coating process, for example.

With reference to FIG. 1C, the light-pipe material 116 outside the light pipe 112 is removed by performing a chemical mechanical polishing process on the light-pipe material 116 with use of a fluff polishing pad 200, so as to form a light-pipe material layer 116a in the light pipe 112, wherein the light-pipe material layer 116a has a recessed curved surface S. Since the recessed curved surface S may redirect the incident light to capture and gather more incident light in the light sensing region 102, the light sensitivity of the image sensing device is improved efficiently. The recessed curved surface S has a curvature radius of 636 nm-791 nm, for example. The light-pipe material layer 116a has a refractive index of 1.7-1.9, for example. In addition, a slurry used in the chemical mechanical polishing process is CeO₂, SiO₂, or a combination thereof, for example. Use of the above-mentioned slurry helps to form the recessed curved surface S. A polishing pressure used in the chemical mechanical polishing process is 2.2 psi-3.2 psi, for example.

The refractive index of the light-pipe material layer 116a is greater than a refractive index of a previous light transmission medium, for example, such that the incident light is refracted according to the Snell's law so as to capture and gather more incident light in the light sensing region 102 and thereby further improve the light sensitivity. Moreover, the refractive index of the light-pipe material layer 116a is greater than the refractive index of the dielectric layer 106, for example. Under the condition of the Snell's law, the dielectric layer 106 may cause the incident light that reaches the side wall of the light pipe 112 to be totally reflected, so as to further improve the light sensitivity.

It is known from the above embodiment that, in the light pipe structure fabricated by the method described above, the light-pipe material layer 116a is formed with the recessed curved surface S that redirects the incident light for capturing and gathering more incident light to directly enter the light sensing region 102. Thus, the number of times of light refraction and light reflection on the side wall of the light pipe 112 and loss of light energy are reduced to efficiently improve the light sensitivity of the image sensing device.

The light pipe structure of the image sensing device of this embodiment is described hereinafter with reference to FIG. 1C. The light pipe structure includes the substrate 100, the dielectric layer 106, and the light-pipe material layer 116a. The substrate 100 has the light sensing region 102 therein. The substrate 100 may further include the isolation regions 104. The dielectric layer 106 is disposed on the substrate 100. The dielectric layer 106 has the light pipe 112 therein, and the light pipe 112 is located above the light sensing region 102. The dielectric layer 106 may further include the interconnect structure 108 and the light-blocking metal layer 110 located above the interconnect structure 108. In this embodiment, the interconnect structure 108 includes the first metal layer 108a, the second metal layer 108b, and the third metal layer 108c, for example. The light-pipe material layer 116a is disposed in the light pipe 112 and has the recessed curved surface S. The light pipe structure may further include the protection layer 114. The protection layer 114 is disposed conformally on the dielectric layer 106, and a portion of the protection layer 114 is located between the light-pipe material layer 116a and the dielectric layer 106. Details of the material, property, and efficacy of each element in the light pipe structure have been specified above and thus are not repeated hereinafter.

To sum up, in the light pipe structure of the image sensing device and the fabricating method thereof described in the above embodiments, the light-pipe material layer is formed with the recessed curved surface that redirects the incident light for capturing and gathering more incident light to directly enter the light sensing region. Thus, the light sensitivity of the image sensing device is improved efficiently.

It will be apparent to those skilled in the art that various modifications and variations can be made to the disclosed embodiments without departing from the scope or spirit of the invention. In view of the foregoing, it is intended that the invention covers modifications and variations of this disclosure provided that they fall within the scope of the following claims and their equivalents.

What is claimed is:

1. A light pipe structure of an image sensing device, comprising:
a substrate, in which a light sensing region is disposed;
a dielectric layer disposed on the substrate, wherein the dielectric layer has a light pipe located above the light sensing region; and
a light-pipe material layer disposed in the light pipe and having a recessed curved surface.

2. The light pipe structure of the image sensing device according to claim 1, wherein the recessed curved surface has a curvature radius of 636 nm-791 nm.

3. The light pipe structure of the image sensing device according to claim 1, wherein the light-pipe material layer has a refractive index of 1.7-1.9.

4. The light pipe structure of the image sensing device according to claim 1, wherein a refractive index of the light-pipe material layer is greater than a refractive index of a previous light transmission medium.

5. The light pipe structure of the image sensing device according to claim 1, further comprising a protection layer conformally disposed on the dielectric layer, wherein a portion of the protection layer is located between the light-pipe material layer and the dielectric layer.

6. A fabricating method of a light pipe structure of an image sensing device, the fabricating method comprising:
providing a substrate, in which a light sensing region is formed;
forming a dielectric layer on the substrate;
forming a light pipe in the dielectric layer by removing a portion of the dielectric layer above the light sensing region; and
forming a light-pipe material layer in the light pipe, wherein the light-pipe material layer has a recessed curved surface.

7. The fabricating method of the light pipe structure of the image sensing device according to claim 6, wherein a forming method of the light-pipe material layer comprises:
forming a light-pipe material on the dielectric layer to fill the light pipe; and
removing the light-pipe material outside the light pipe by performing a chemical mechanical polishing process on the light-pipe material using a fluff polishing pad.

8. The fabricating method of the light pipe structure of the image sensing device according to claim 7, wherein a slurry used in the chemical mechanical polishing process is CeO₂, SiO₂, or a combination thereof.

9. The fabricating method of the light pipe structure of the image sensing device according to claim 7, wherein a polishing pressure of the chemical mechanical polishing process is 2.2 psi-3.2 psi.

10. The fabricating method of the light pipe structure of the image sensing device according to claim 6, further comprising conformally forming a protection layer on the dielectric layer after forming the light pipe and before Ruining the light-pipe material layer.
